(19) United States
(12) Patent Application Publication
(10) Pub. No.: US 2026/0165195 A1
(43) Pub. Date: Jun. 11, 2026

(54) SEMICONDUCTOR DEVICE

(71) Applicant: FUJI ELECTRIC CO., LTD., Kawasaki-shi (JP)

(72) Inventor: Yuto UEMATSU, Kawasaki-shi (JP)

(73) Assignee: FUJI ELECTRIC CO., LTD., Kawasaki-shi (JP)

(21) Appl. No.: 19/375,875

(22) Filed: Oct. 31, 2025

(30) Foreign Application Priority Data
Dec. 6, 2024 (JP) 2024-212958

(51) Int. Cl. H01L 23/047; H01L 23/00; H01L 23/373; H01L 25/07; H10D 80/20

(52) U.S. Cl. CPC H10W 76/134; H10D 80/20; H10W 40/255; H10W 90/00; H10W 72/886; H10W 90/734; H10W 90/764

(57) ABSTRACT

A semiconductor device, including: a multilayer substrate with a semiconductor element mounted thereon; and a main terminal having: a bonded portion bonded to a surface of the multilayer substrate, and extending in an extending direction; a vertical portion extending in a vertical direction; an extending portion extending toward outside of the multilayer substrate, and a bent portion interposed between the vertical portion and the extending portion, to thereby form: a narrow portion that includes the bonded portion, the vertical portion, the bent portion, and a first part of the extending portion, and a wide portion that includes a second part of the extending portion different from the first part. In a width direction perpendicular to the vertical direction and the extending direction, the wide portion is wider than the narrow portion, and the narrow portion is located on one end side of the wide portion.

### CROSS-REFERENCE TO RELATED APPLICATIONS

This application is based upon and claims the benefit of priority to Japanese Patent Application No. 2024-212958, filed on Dec. 6, 2024, the entire contents of which are incorporated herein by reference.

### BACKGROUND OF THE INVENTION

### 1. Technical Field

The present invention relates to a semiconductor device.

### 2. Description of the Related Art

Conventionally, in a semiconductor device used in a power conversion device or the like, a main terminal connected to an external conductor is bonded to a multilayer substrate having a semiconductor element (see, for example, JP H10-173126 A, JP H11-345926 A, JP 2019-135793 A, and JP 2011-018933 A). In this type of main terminal, a portion to be bonded to the multilayer substrate and an external connection portion to be bonded to the external conductor have different heights and, thus, the main terminal extends while being bent between the portion to be bonded and the external connection portion.

### SUMMARY OF THE INVENTION

In the meantime, some main terminals are configured such that a portion to be bonded is formed as a narrow portion and an external connection portion is formed as a wide portion in order to reduce the occupied area in a multilayer substrate. In a case where the portion to be bonded of the main terminal is bonded to the multilayer substrate using ultrasonic bonding or the like, stress concentrates in a region where a portion where the width increases from the narrow portion toward the wide portion overlaps with the bent portion of the main terminal, so that a crack is likely to occur.

According to one aspect, an object of the present invention is to provide a semiconductor device that can reduce the occurrence of a crack in a main terminal.

In one aspect, a semiconductor device includes a multilayer substrate on which a semiconductor element is mounted and a main terminal bonded to the multilayer substrate. The main terminal includes a narrow portion including a vertical portion extending in a direction perpendicular to a surface of the multilayer substrate on which the semiconductor element is mounted, and a wide portion having a width in a width direction perpendicular to a thickness direction and an extending direction of the main terminal larger than a width of the narrow portion. The narrow portion is located on one end side of the wide portion in the width direction. The main terminal is provided with an extending portion extending toward outside of the multilayer substrate with a bent portion interposed therebetween from an end of the vertical portion on a side opposite to the multilayer substrate. The narrow portion extends at least over the vertical portion, the bent portion, and a part of the extending portion. The wide portion extends at least over another part of the extending portion different from the part of the extending portion.

According to the above aspect, in the semiconductor device, the occurrence of a crack in the main terminal can be reduced.

### BRIEF DESCRIPTION OF THE DRAWINGS

FIG. 1 is a plan view illustrating a schematic configuration of a semiconductor device according to a first embodiment;

FIG. 2 is a cross-sectional view illustrating a schematic configuration of the semiconductor device according to the first embodiment;

FIG. 3 is a perspective view illustrating a part of a P terminal in the first embodiment;

FIG. 4 is a perspective view illustrating a part of a P terminal in a second embodiment;

FIG. 5 is a plan view illustrating a schematic configuration of a semiconductor device according to the second embodiment;

FIG. 6 is a perspective view illustrating the entirety of a P terminal in a third embodiment; and

FIG. 7 is a perspective view illustrating a part of a P terminal in a comparative example.

### DETAILED DESCRIPTION

Hereinafter, semiconductor devices 1 and 2 according to first to third embodiments of the present invention will be described in detail with reference to the drawings. Note that an X axis, a Y axis, and a Z axis in each of the drawings to be referred to are illustrated for the purpose of defining directions and surfaces in the exemplified semiconductor devices 1 and 2 and the like. The X, Y, and Z axes are orthogonal to each other and form a right-handed system. In the following description, a Z direction may be referred to as an up-down direction. Further, a surface including the X axis and the Y axis may be referred to as an upper surface or a lower surface. Such directions and surfaces are terms used for convenience of description. Thus, the correspondence relationship with each of the X, Y, and Z directions may change depending on the attachment posture of the semiconductor devices 1 and 2. For example, in the present specification, a surface facing the positive side in the Z direction (+Z direction) in a member forming the semiconductor devices 1 and 2 is referred to as an upper surface, and a surface facing the negative side in the Z direction (-Z direction) in the member is referred to as a lower surface. However, the surface facing the negative side in the Z direction may be referred to as the upper surface, and the surface facing the positive side in the Z direction may be referred to as the lower surface. Further, in the present specification, the plan view means a case where the upper surface (XY plane) of the semiconductor devices 1 and 2 or the like is viewed in a perspective manner from the positive side in the Z direction toward the negative side in the Z direction.

An aspect ratio and a size relationship between the members in each drawing are merely schematically represented, and do not necessarily coincide with a relationship in the semiconductor devices 1 and 2 or the like actually manufactured. For convenience of description, the size relationship between the members may be exaggerated. Further, the shapes of the same members may be different between different drawings.

In the following description, as an example of the semiconductor devices 1 and 2 according to the first to third embodiments, a device applied to a power conversion device such as an inverter device for an in-vehicle or industrial motor will be described. Therefore, in the following description, detailed description of the same or similar configuration, function, operation, assembly method, and the like as those of a known semiconductor device will be omitted.

### First Embodiment

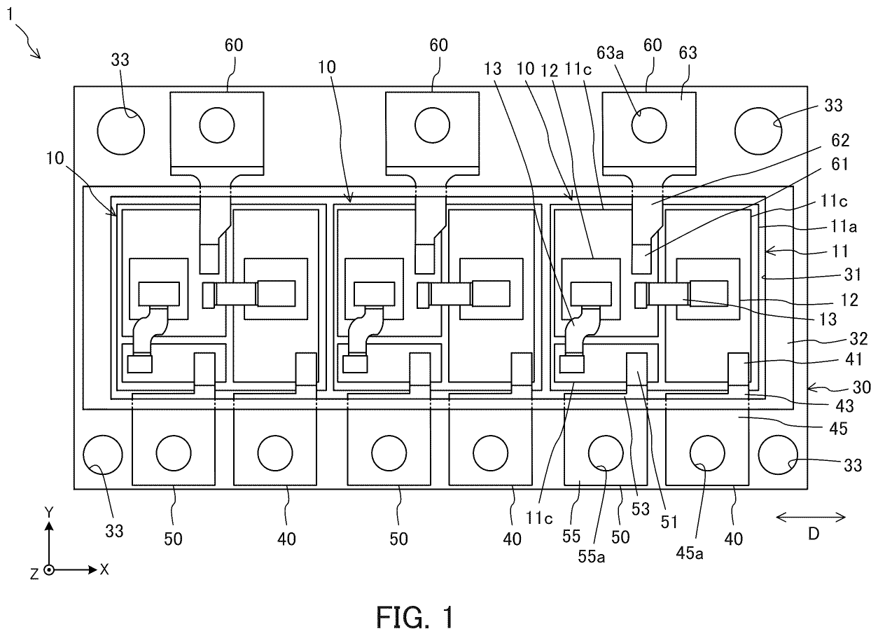

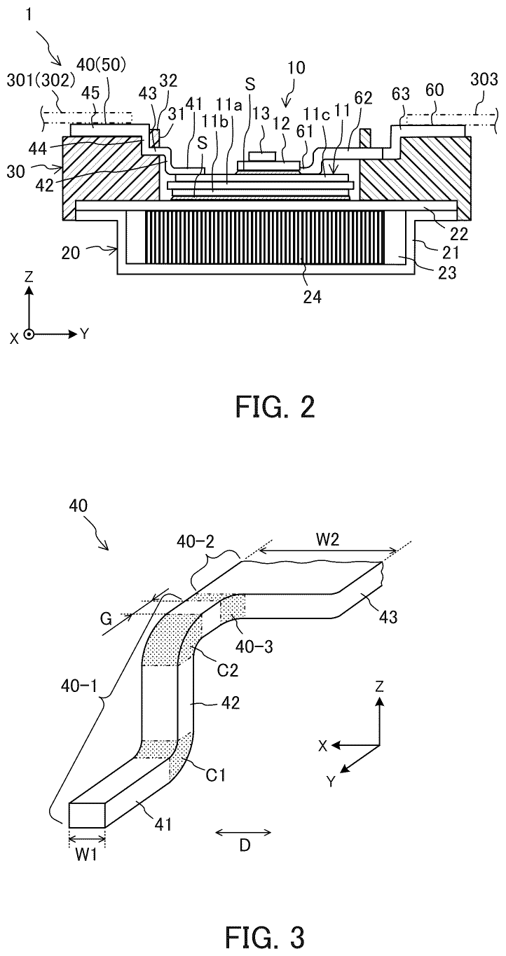

FIGS. 1 and 2 are a plan view and a cross-sectional view illustrating a schematic configuration of a semiconductor device 1 according to the first embodiment, respectively. In FIGS. 1 and 2, a direction parallel to a surface of a multilayer substrate 11 on which a semiconductor element 12 is mounted is defined as an X direction and a Y direction, and a direction perpendicular to the mounting surface (a thickness direction of the semiconductor element 12) is defined as a Z direction.

The semiconductor device 1 illustrated in FIGS. 1 and 2 includes three unit modules 10 and a case 30 that accommodates therein the three unit modules 10. The semiconductor device 1 is used, for example, in a state of being fixed to a cooler 20 (see FIG. 2). The semiconductor device 1 is, for example, a power semiconductor device used in a traction inverter for an electric vehicle.

Each of the three unit modules 10 illustrated in FIG. 1 includes the multilayer substrate 11 on which the semiconductor element 12 is mounted. The three unit modules 10 are arranged side by side in the X direction which is the longitudinal direction of the semiconductor device 1. The three unit modules 10 constitute, for example, a U phase, a V phase, and a W phase to thereby collectively form a three-phase inverter circuit. Note that the unit modules 10 may be each referred to as a power cell or a semiconductor unit. The number of unit modules 10 to be disposed is at least one.

The multilayer substrate 11 illustrated in FIG. 2 is configured with, for example, a direct copper bonding (DCB) substrate, an active metal brazing (AMB) substrate, a metal base substrate, or the like. For example, the multilayer substrate 11 includes an insulating layer 11a, a heat dissipation layer 11b disposed on a lower surface of the insulating layer 11a, and a plurality of circuit layers 11c disposed on an upper surface of the insulating layer 11a. The multilayer substrate 11 is formed in, for example, a rectangular shape in plan view.

For example, the insulating layer 11a is formed of an insulating material, such as a ceramic material such as alumina (Al₂O₃) aluminum nitride (AlN), or silicon nitride (Si₃N₄), a resin material such as epoxy, or an epoxy resin material using a ceramic material as a filler. Note that the insulating layer 11a may be referred to as an insulating plate or an insulating film.

The heat dissipation layer 11b has a predetermined thickness in the Z direction and is formed on the lower surface of the insulating layer 11a. The heat dissipation layer 11b is made of, for example, a metal plate having good thermal conductivity such as copper or aluminum. The heat dissipation layer 11b is bonded to an upper surface of the cooler 20 (top plate 22) or bonded to a heat dissipation plate (not illustrated) disposed between the heat dissipation layer 11b and the cooler 20 by a bonding material such as solder S.

The three circuit layers 11c are formed on the upper surface of the insulating layer 11a. The number of circuit layers 11c formed on the upper surface of the insulating layer 11a may be any number of one or more. The circuit layers 11c are metal layers such as copper foils, and are formed in island shapes on the insulating layer 11a in a state electrically insulated from one another. The circuit layers 11c may be each referred to as a circuit board or a circuit pattern.

As illustrated in FIG. 2, the semiconductor element 12 is disposed on the mounting surface, which is the upper surface of the multilayer substrate 11 (circuit layer 11c), via the solder S. In FIG. 1, two semiconductor elements 12 are illustrated per multilayer substrate 11, but the number of semiconductor elements 12 is any number. For example, the semiconductor elements 12 are each achieved with a semiconductor substrate based on silicon (Si), silicon carbide (SiC), gallium nitride (GaN), or diamond, and are each square or rectangular in shape in plan view.

Examples of the semiconductor element 12 include a switching element such as an insulated gate bipolar transistor (IGBT) or a power metal oxide semiconductor field effect transistor (MOSFET), and a diode such as a free wheeling diode (FWD). Such a switching element and a diode may be made in antiparallel connection. Alternatively, examples of the semiconductor element 12 include a reverse conducting (RC)-IGBT element of an IGBT and an FWD in unification, a power MOSFET element, and a reverse blocking (RB)-IGBT element highly resistant to a reverse bias. In particular, in the RC-IGBT element, the internal circuit can be downsized by bidirectional energization, and in turn, the RC-IGBT element can be particularly effectively used as the semiconductor element 12.

The semiconductor elements 12 are each made in electrically conductive connection with a predetermined circuit layer 11c via a metal wiring board 13. For example, the metal wiring board 13 is made of a metal material such as a copper material, a copper-alloy-based material, an aluminum-alloy-based material, or an iron-alloy-based material, and is formed by bending through pressing working or the like. For example, the semiconductor element 12 and the metal wiring board 13 are bonded to each other with a bonding material such as solder. The metal wiring board 13 may be referred to as a lead frame. Note that, instead of the metal wiring board 13, a connecting member, such as a conductive wire, may be disposed.

The case 30 is formed in a rectangular frame shape having an opening 31 at the center. The three unit modules 10 described above are housed in the opening 31 having a rectangular shape in plan view. That is, the three unit modules 10 are housed in the space defined by the frame-shaped case 30. Thereby, the opening 31 functions as an example of a housing region in which the multilayer substrate 11 is accommodated. As an example, a wall portion 32 surrounding the opening 31 of the case 30 is provided. The wall portion 32 rises from the case 30 toward the positive side in the Z direction at a predetermined height.

The case 30 is provided with main terminals (a P terminal 40, an N terminal 50, and an M terminal 60) illustrated in FIG. 1 that function as external connection terminals for connection with external conductors 301, 302, and 303 (see two-dot-dash lines in FIG. 2), and a control terminal for control (not illustrated). A single P terminal 40, a single N terminal 50, and a single M terminal 60 are disposed per single unit module 10. The P terminal 40, the N terminal 50, and the M terminal 60 can be integrally disposed in the case 30 using insert molding.

The P terminal 40 and the N terminal 50 are located on the negative side in the Y direction with respect to the multilayer substrate 11. On the other hand, the M terminal 60 is located on the positive side in the Y direction with respect to the multilayer substrate 11.

The P terminal 40, the N terminal 50, and the M terminal 60 are preferably formed, for example, by bending a metal material such as a copper material, a copper-alloy-based material, an aluminum-alloy-based material, or an iron-alloy-based material, through pressing working or the like.

The P terminal 40 includes a portion to be bonded 41, a first vertical portion 42, an extending portion 43, a second vertical portion 44, and an external connection portion 45. As will be detailed later, the portion to be bonded 41, the extending portion 43, and the external connection portion 45 extend parallel to the surface (XY plane) of the multilayer substrate 11 on which the semiconductor element 12 is mounted and extend in the Y direction, while the first vertical portion 42 and the second vertical portion 44 extend in a direction (XZ plane) perpendicular to the mounting surface and extend in the Z direction.

The N terminal 50 can be formed to have the same shape as the P terminal 40, and includes a portion to be bonded 51, an extending portion 53, an external connection portion 55, and a first vertical portion and a second vertical portion (not illustrated), similarly to the P terminal 40.

In the M terminal 60, a portion to be bonded 61 that is bonded to the multilayer substrate 11, an extending portion 62, and an external connection portion 63 are continuously provided with a vertical portion (not illustrated) therebetween.

The portions to be bonded 41, 51, and 61 of the main terminals 40, 50, and 60 are bonded to the multilayer substrate 11 (circuit layer 11c) using ultrasonic bonding, for example. The P terminal 40 may be referred to as a positive terminal. The N terminal 50 may be referred to as a negative terminal. The M terminal 60 may be referred to as an intermediate terminal. The external connection portions 45, 55, and 63 of the P terminal 40, the N terminal 50, and the M terminal 60 are connected to the external conductors 301, 302, and 303 illustrated in FIG. 2 by, for example, fastening in screw holes 45a, 55a, and 63a.

As an example, as illustrated in FIG. 2, the P terminal 40 (N terminal 50) is ultrasonically bonded to the circuit layer 11c of the multilayer substrate 11 at the portion to be bonded 41. In addition, the P terminal 40 (N terminal 50) extends toward the outside (negative side in the Y direction) of the multilayer substrate 11 at the extending portion 43. Further, the P terminal 40 (N terminal 50) penetrates the case 30 at the extending portion 43 and the second vertical portion 44, and is located on the upper surface of the case 30 at the external connection portion 45. The M terminal 60 is ultrasonically bonded to the circuit layer 11c of the multilayer substrate 11 at the portion to be bonded 61, penetrates the case 30 at the extending portion 62, and is located on the upper surface of the case 30 at the external connection portion 63. As described above, the M terminal 60 is also provided with vertical portions between the portion to be bonded 61 and the extending portion 62 as well as between the extending portion 62 and the external connection portion 63.

As illustrated in FIG. 1, the case 30 is formed with a plurality of through holes 33 along an outer peripheral edge thereof. For example, the through holes 33 each serve as a hole through which a screw for fixing the semiconductor device 1 and an external device such as an inverter device (not illustrated) together is inserted.

Note that, for example, resin for the case 30 can be selected from insulating resin such as polyphenylene sulfide (PPS), polybutylene terephthalate (PBT), polybutyl acrylate (PBA), polyamide (PA), acrylonitrile butadiene styrene (ABS), a liquid crystal polymer (LCP), polyether ether ketone (PEEK), polybutylene succinate (PBS), urethane, and silicone. In addition, the resin to be selected may be a mixture of two or more types of resins. The resin may contain a filler (for example, a glass filler) for improving strength or functionality.

In addition, sealing resin (not illustrated) injected into the housing region defined by the opening 31 of the frame-shaped case 30 seals the multilayer substrate 11, the semiconductor element 12 mounted on the multilayer substrate 11, the metal wiring board 13, a part of the P terminal 40, a part of the N terminal 50, and a part of the M terminal 60 in the housing region. The sealing resin is made of thermosetting resin. Preferably, the sealing resin contains at least one of epoxy, silicone, urethane, polyimide, polyamide, and polyamide-imide. As the sealing resin, for example, epoxy resin containing a filler is preferable because of its insulation, heat resistance, and heat dissipation. The sealing into the inner space may be gel sealing using silicone gel or the like.

As illustrated in FIG. 2, the cooler 20 includes a housing portion 21 and the top plate 22. The housing portion 21 is disposed below the top plate 22, has a rectangular parallelepiped shape with an open upper surface and a flange portion therearound, and has a cavity 23 therein. The cavity 23 functions as a refrigerant circulation portion through which a refrigerant such as water circulates. The housing portion 21 is preferably fixed to the top plate 22 and the case 30 at the peripheral flange portion. The top plate 22 has a horizontally arranged rectangular plate shape. The housing portion 21 and the top plate 22 are made of metal containing aluminum, for example.

A cooling fin 24 is disposed inside the cavity 23. The cooling fin 24 is provided on the lower surface of the top plate 22. The cooling fin 24 mainly transfers heat generated by the semiconductor element 12 to the above-described refrigerant. Note that the cooler 20 is a jacket-integrated cooler having a refrigerant flow path passing through the cooling fin 24, but may be an open-fin-type cooler, a flat-base-type cooler, or the like in which the cooling fin is exposed to the outside, and is not particularly limited. The semiconductor device 1 can be referred to as the semiconductor device 1 independent of whether or not the semiconductor device 1 includes the cooler 20. The semiconductor device 1 including the cooler 20 can also be referred to as a semiconductor system.

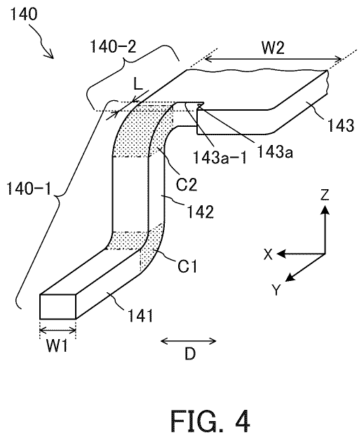

Next, the P terminal 40 will be described in more detail with reference to FIG. 3. In FIG. 3, the region of the P terminal 40 on the negative side in the Y direction in the extending portion 43, the second vertical portion 44, and the external connection portion 45 are omitted. As described above, since the N terminal 50 can have the same shape as the P terminal 40, the detailed description of the N terminal 50 is omitted.

As illustrated in FIG. 3, the portion to be bonded 41 of the P terminal 40 extends in a direction parallel to the mounting surface (XY plane) and extends in the Y direction. The first vertical portion 42 extends in a direction (Z direction) perpendicular to the mounting surface (XY plane) with a first bent portion C1 (illustrated with halftone dots surrounded by a two-dot-dash line) interposed between the first vertical portion 42 and the portion to be bonded 41. The extending portion 43 extends parallel to the mounting surface (XY plane) with a second bent portion C2 (illustrated with halftone dots surrounded by a two-dot-dash line) interposed between the extending portion 43 and the first vertical portion 42, and extends in the Y direction. The first bent portion C1 and the second bent portion C2 are parts serving to bend the P terminal 40 at an angle of about 90 degrees, but the first bent portion C1 and the second bent portion C2 may also be referred to as curve portions where the P terminal 40 is curved at an angle of about 90 degrees.

The P terminal 40 includes a narrow portion 40-1, a wide portion 40-2, and an expanding portion 40-3 (illustrated with halftone dots surrounded by a two-dot dash line). The width W1 of the narrow portion 40-1 in the width direction D (X direction) perpendicular to the thickness direction and the extending direction of the P terminal 40 is shorter than the width W2 of the wide portion 40-2. For example, the width W1 of the narrow portion 40-1 is equal to or less than half of the width W2 of the wide portion 40-2.

The narrow portion 40-1 is located on one end side (end on the positive side in the X direction) of the wide portion 40-2 in the width direction D. An end of the narrow portion 40-1 on the positive side in the X direction and an end of the wide portion 40-2 on the positive side in the X direction have the same position in the X direction. The expanding portion 40-3 is located between the narrow portion 40-1 and the wide portion 40-2, and the width of the expanding portion 40-3 gradually increases from the narrow portion 40-1 toward the wide portion 40-2. The expanding portion 40-3 desirably has an R portion (curved portion) at which an end thereof on the other end side (negative side in the X direction) located on the opposite side to one end of the wide portion 40-2 is curved.

The narrow portion 40-1 extends over the portion to be bonded 41, the first bent portion C1, the first vertical portion 42, the second bent portion C2, and a part of the extending portion 43 (a region closer to the second bent portion C2 than the expanding portion 40-3). That part of the extending portion 43 is desirably located in the opening 31 (housing region for the multilayer substrate 11) of the case 30 illustrated in FIG. 1. That is, the narrow portion 40-1 is desirably located in the opening 31 as a whole. Incidentally, the narrow portion 40-1 only needs to extend at least over the first vertical portion 42, the second bent portion C2, and a part of the extending portion 43, and for example, the portion to be bonded 41 may be formed to be wider than the narrow portion 40-1. In such a case, a part narrower than the wide portion 40-2 can be regarded as the narrow portion 40-1.

The wide portion 40-2 extends over another part of the extending portion 43 (region on the negative side in the Y direction with respect to the expanding portion 40-3), the second vertical portion 44 and the external connection portion 45 illustrated in FIG. 2. As described above, the P terminal 40 penetrates the case 30 at the extending portion 43 and the second vertical portion 44, and is located on the upper surface of the case 30 at the external connection portion 45. The wide portion 40-2 penetrates the case 30 and is located on the upper surface of the case 30 as described above. Incidentally, the wide portion 40-2 only needs to extend at least over that another part of the extending portion 43, and for example, the second vertical portion 44 and the external connection portion 45 may be formed to be wider than the wide portion 40-2. In such a case, the second vertical portion 44 and the external connection portion 45 are each wider than the narrow portion 40-1 and, thus, they may be regarded as the wide portion 40-2. That is, a part, of the second vertical portion 44 and the external connection portion 45, wider than the narrow portion 40-1 can be regarded as the wide portion 40-2.

Since the narrow portion 40-1 extends over a part of the extending portion 43 as described above, the expanding portion 40-3 is located closer to the extending portion 43 than the second bent portion C2 with a gap G interposed between the expanding portion 40-3 and the second bent portion C2 that is provided between the first vertical portion 42 and the extending portion 43. That is, the expanding portion 40-3 is provided at a position not overlapping the second bent portion C2. The expanding portion 40-3 may be adjacent to the second bent portion C2 in the extending direction (the Y direction in the extending portion 43), but is desirably located with the gap G interposed between the expanding portion 40-3 and the second bent portion C2.

In the first embodiment described above, the semiconductor device 1 includes the multilayer substrate 11 on which the semiconductor element 12 is mounted and the P terminal 40 (an example of the main terminal) bonded to the multilayer substrate 11. The P terminal 40 includes the narrow portion 40-1 and the wide portion 40-2. The narrow portion 40-1 includes the first vertical portion 42 (an example of a vertical portion) extending in a direction (Z direction) perpendicular to the surface (XY plane) of the multilayer substrate 11 on which the semiconductor element 12 is mounted. The width W2 of the wide portion 40-2 in the width direction D (X direction) perpendicular to the thickness direction and the extending direction of the P terminal 40 is wider than the narrow portion 40-1 (width W1). The narrow portion 40-1 is located on one end side of the wide portion 40-2 in the width direction D. The P terminal 40 is provided with the extending portion 43 that extends toward the outside of the multilayer substrate 11 with the second bent portion C2 (an example of a bent portion) interposed therebetween from an end (end on the positive side in the Z direction) of the first vertical portion 42 on a side opposite to the multilayer substrate 11. The narrow portion 40-1 extends at least over the first vertical portion 42, the second bent portion C2, and a part of the extending portion 43 (for example, a region on the positive side in the Y direction with respect to the expanding portion 40-3). The wide portion 40-2 extends at least over another part of the extending portion 43 different from the part of the extending portion 43 mentioned above (for example, a region on the negative side in the Y direction with respect to the expanding portion 40-3).

Here, as in a P terminal 540 of a comparative example illustrated in FIG. 7, a case where a narrow portion 540-1 extends over a portion to be bonded 541, a first bent portion C1, a first vertical portion 542, and a part of a second bent portion C2, and an expanding portion 540-3 extends over the second bent portion C2 and an extending portion 543 will be considered.

In such a case, the second bent portion C2 and the expanding portion 540-3 overlap in an overlapping region A (illustrated with hatching). Then, stress is likely to occur in the second bent portion C2 and the expanding portion 540-3 due to vibrations or the like when the portion to be bonded 541 is ultrasonically bonded to the multilayer substrate 11 (circuit layer 11c). Therefore, stress concentrates on the overlapping region A between the second bent portion C2 and the expanding portion 540-3, and a crack is likely to occur in the overlapping region A in the P terminal 540.

Similarly to the comparative example, the narrow portion 40-1 of the first embodiment is located on one side of the wide portion 40-2 and, thus, it is effective from the viewpoint of wiring flexibility and a simplified structure of the multilayer substrate 11 (circuit layer 11c), but it can be said that stress is likely to be generated due to vibrations or the like by the ultrasonic bonding described above. However, unlike the comparative example illustrated in FIG. 7, the narrow portion 40-1 extends over the first vertical portion 42, the second bent portion C2, and a part of the extending portion 43, so that the second bent portion C2 and the expanding portion 40-3 do not overlap. This allows the stress on the P terminal 40 to be dispersed at the second bent portion C2 and the expanding portion 40-3, so that cracks are less likely to occur in the P terminal 40. Therefore, according to the first embodiment, the occurrence of cracks in the main terminals (the P terminal 40 and the N terminal 50) can be prevented. As a result, reducing the failure in the semiconductor device 1 caused by cracks in the main terminal can stabilize or prolong the lifetime of the semiconductor device 1, and can also prevent an increase in heat generation at the main terminal due to the cracks of the main terminal.

In the first embodiment, the expanding portion 40-3 of the P terminal 40 is located between the narrow portion 40-1 and the wide portion 40-2, and the width in the width direction D gradually increases from the narrow portion 40-1 (width W1) toward the wide portion 40-2 (width W2). The expanding portion 40-3 is located closer to the extending portion 43 than the second bent portion C2 at a gap G from the second bent portion C2.

As described above, the second bent portion C2 and the expanding portion 40-3 where the stress is likely to concentrate are located with the gap G therebetween, which further reduces the occurrence of cracks in the P terminal 40.

In addition, in the first embodiment, the semiconductor device 1 further includes the opening 31 (an example of the housing region) in which the multilayer substrate 11 is accommodated and the case 30 having the wall portion 32 surrounding the opening 31 (an example of the housing region), in which the narrow portion 40-1 is located closer to the opening 31 than the wall portion 32, and the wide portion 40-2 extends from the opening 31 through the case 30.

In the first embodiment, the P terminal 40 is bonded to the multilayer substrate 11 using ultrasonic bonding.

The P terminal 40 is bonded to the multilayer substrate 11 using ultrasonic bonding in this manner. This reduces the size and cost of the semiconductor device 1, and also reduces the inductance (Ls) by reducing the wiring distance. The second bent portion C2 and the expanding portion 40-3 in which stress is particularly likely to occur due to vibrations at the time of ultrasonic bonding do not overlap each other as described above and, thus, it is possible to prevent the occurrence of cracks more effectively.

In the first embodiment, the portion to be bonded 41 extends parallel (Y direction) to the surface (XY plane) of the multilayer substrate 11 on which the semiconductor element 12 is mounted and is bonded to the multilayer substrate 11. The narrow portion 40-1 extends over the portion to be bonded 41.

Therefore, by narrowing the width W1 of the portion to be bonded 41, the occupied area in the multilayer substrate 11 can be reduced, the wiring flexibility can be increased, and the structure can be simplified such as downsizing of the semiconductor device 1.

In the first embodiment, the external connection portion 45 extends parallel to the surface (XY plane) of the multilayer substrate 11 on which the semiconductor element 12 is mounted and is connected to the external conductor 301. The wide portion 40-2 extends over the external connection portion 45.

This increases the width W2 of the external connection portion 45 of the P terminal 40 and increases the area thereof, which prevents the P terminal 40 from generating heat, and facilitates connection of the external conductor 301.

In the first embodiment, the second vertical portion 44 is provided between the extending portion 43 and the external connection portion 45, and extends in the direction (Z direction) perpendicular to the surface (XY plane) of the multilayer substrate 11 on which the semiconductor element 12 is mounted. The wide portion 40-2 extends over the second vertical portion 44.

As a result, in the P terminal 40, the width W2 of the wide portion 40-2 can be made constant over the extending portion 43 (region on the negative side in the Y direction with respect to the expanding portion 40-3), the second vertical portion 44, and the external connection portion 45. Therefore, the configuration of the P terminal 40 can be simplified, and the P terminal 40 can be easily manufactured.

### Second Embodiment

FIG. 4 is a perspective view illustrating a part of a P terminal 140 in the second embodiment.

The P terminal 140 illustrated in FIG. 4 is provided with a cutout 143a in an extending portion 143, and a narrow portion 140-1 is extended in the extending direction (-Y direction in extending portion 143) in a region where the cutout 143a is provided. Since the other configurations of the P terminal 140 can be similar to the configuration of the P terminal 40 in the first embodiment, a detailed description of the P terminal 140 is omitted.

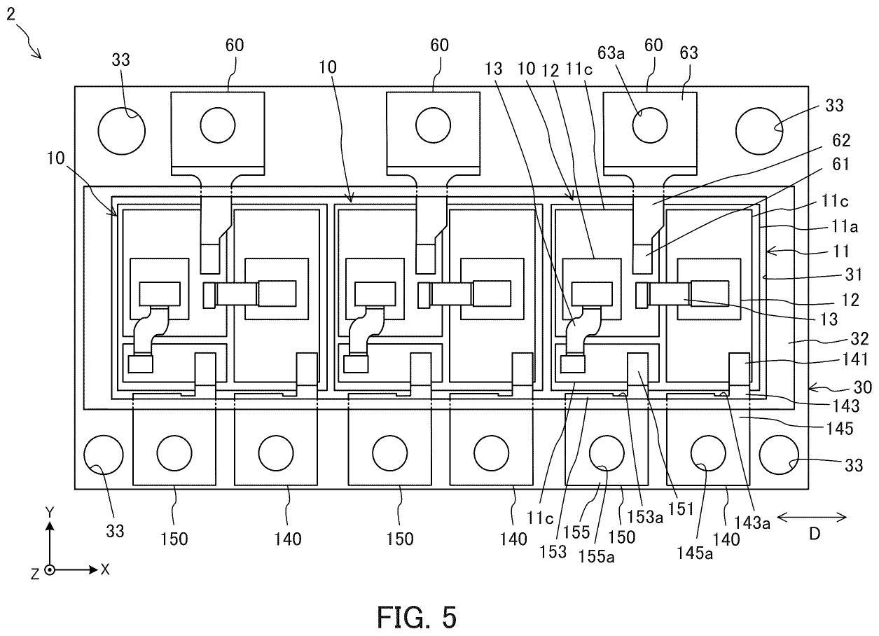

As with the P terminal 40, the P terminal 140 includes a portion to be bonded 141, a first vertical portion 142, the extending portion 143, a second vertical portion 144, and an external connection portion 145 (screw hole 145a). An N terminal 150 illustrated in FIG. 5 can also have the same shape as the P terminal 140 also in the second embodiment. Accordingly, as with the P terminal 140, the N terminal 150 includes a portion to be bonded 151, an extending portion 153, an external connection portion 155 (screw hole 155a), and a first vertical portion and a second vertical portion (not illustrated), and a cutout (not illustrated). Further, the device configuration of the semiconductor device 2 illustrated in FIG. 5 can be similar to that of the semiconductor device 1 illustrated in FIG. 1 except for the P terminal 140 and the N terminal 150.

As illustrated in FIG. 4, the portion to be bonded 141 of the P terminal 140 extends in a direction parallel to the mounting surface (XY plane) and extends in the Y direction. The first vertical portion 142 extends in a direction (Z direction) perpendicular to the mounting surface (XY plane) with a first bent portion C1 (illustrated with halftone dots surrounded by a two-dot-dash line) interposed between the first vertical portion 142 and the portion to be bonded 141. The extending portion 143 extends parallel to the mounting surface (XY plane) with a second bent portion C2 (illustrated with halftone dots surrounded by a two-dot-dash line) interposed between the extending portion 143 and the first vertical portion 142. The first bent portion C1 and the second bent portion C2 bend the P terminal 140 at an angle of about 90 degrees, but the first bent portion C1 and the second bent portion C2 may also be referred to as curve portions where the P terminal 140 is curved at an angle of about 90 degrees.

The P terminal 140 includes the narrow portion 140-1 and a wide portion 140-2. The width W1 of the narrow portion 140-1 in the width direction D (X direction) is smaller than the width W2 of the wide portion 140-2, and the narrow portion 140-1 is located on one end side (positive side in the X direction) of the wide portion 140-2 in the width direction D.

In the second embodiment, the cutout 143a adjacent to the narrow portion 140-1 in the width direction D (negative side in the X direction) is provided at an end (end on the positive side in the Y direction) of the extending portion 143 on the first vertical portion 142 side. The cutout 143a is provided so as to be recessed in the extending direction from the end of the extending portion 143 on the first vertical portion 142 side. That is, the cutout 143a is provided so as to be recessed toward the side opposite to the second bent portion C2. An end on the positive side in the X direction of the cutout 143a is located at the same position in the X direction as the end on the negative side in the X direction of the narrow portion 140-1. In the second embodiment, the wide portion 140-2 extends over the entire extending portion 143 by providing the cutout 143a. The narrow portion 140-1 is extended in the extending direction (-Y direction in the extending portion 143) in the region where the cutout 143a is provided (extension length L). That is, the end on the side of the extending direction of the narrow portion 140-1 and a bottom portion 143a-1 of the cutout 143a are located on the opposite side (negative side in the Y direction) to the second bent portion C2 with respect to the end on the side of the second bent portion C2 (positive side in the Y direction) of the wide portion 140-2. Further, the second bent portion C2 is located over the negative side in the Y direction with respect to the end on the positive side in the Y direction of the extending portion 143. The wide portion 140-2 extends over the entire extending portion 143 and, thus, it can also be said that the wide portion 140-2 extends over another part of the extending portion 143 different from a part of the extending portion 143 where the narrow portion 140-1 extends.

In the second embodiment, a part where the width W1 of the narrow portion 140-1 expands in the P terminal 140 can be said to be the bottom portion 143a-1 (end on the negative side in the Y direction) of the cutout 143a of the extending portion 143. However, the part where the width W1 expands does not overlap the second bent portion C2 since the narrow portion 140-1 extends over a part of the extending portion 143. The corner of the bottom portion 143a-1 of the cutout 143a on the narrow portion 140-1 side (positive side in the X direction) is a part where the width W1 expands from the narrow portion 140-1. It is thus desirable to gradually increase the width W1 by forming a curved R portion (curved portion) like the expanding portion 40-3 illustrated in FIG. 3.

As illustrated in FIG. 5, the cutout 143a of the extending portion 143 is located in the opening 31. That is, also in the second embodiment, the narrow portion 140-1 illustrated in FIG. 4 is located in the opening 31 as a whole.

In the second embodiment described above also, regarding the same matters as in the first embodiment described above, it is possible to obtain the same effect, that is, the effect of reducing the occurrence of cracks in the main terminal (the P terminal 140 and the N terminal 150). In addition, in the P terminal 140, the cutout 143a is provided in the extending portion 143, which makes it possible to separate the second bent portion C2 and the part where the width W1 is increased from each other. As a result, it is possible to provide a structure in which the second bent portion C2 and the part where the width W1 is increased do not overlap each other without increasing the wiring length of the P terminal 140. This prevents the occurrence of cracks while reducing an increase in inductance.

In the second embodiment, the cutout 143a adjacent to the narrow portion 140-1 in the width direction D is provided in the P terminal 140 (an example of the main terminal). The bottom portion 143a-1 of the cutout 143a is located on the opposite side (negative side in the Y direction) to the second bent portion C2 with respect to the end on the side of the second bent portion C2 (positive side in the Y direction) of the wide portion 140-2 (extension length L).

The cutout 143a is provided in the extending portion 143 as described above. Thereby, the narrow portion 140-1 is extended, and the second bent portion C2 and the part where the width W1 of the narrow portion 140-1 in the width direction D is increased (the bottom portion 143a-1 of the cutout 143a) where stress is likely to concentrate do not overlap each other. This further prevents the occurrence of cracks in the P terminal 140. Further, providing the cutout 143a in the extending portion 143 can extend the end of the wide portion 140-2 (extending portion 143) on the second bent portion C2 side toward the positive side in the Y direction. This increases the area of the wide portion 140-2, which also prevents the P terminal 140 from generating heat.

In addition, also in the second embodiment, the semiconductor device 2 further includes the opening 31 (an example of the housing region) in which the multilayer substrate 11 is accommodated and the case 30 having the wall portion 32 surrounding the opening 31, in which the narrow portion 140-1 and the cutout 143a are located closer to the opening 31 than the wall portion 32, and the wide portion 140-2 extends from the opening 31 through the case 30.

### Third Embodiment

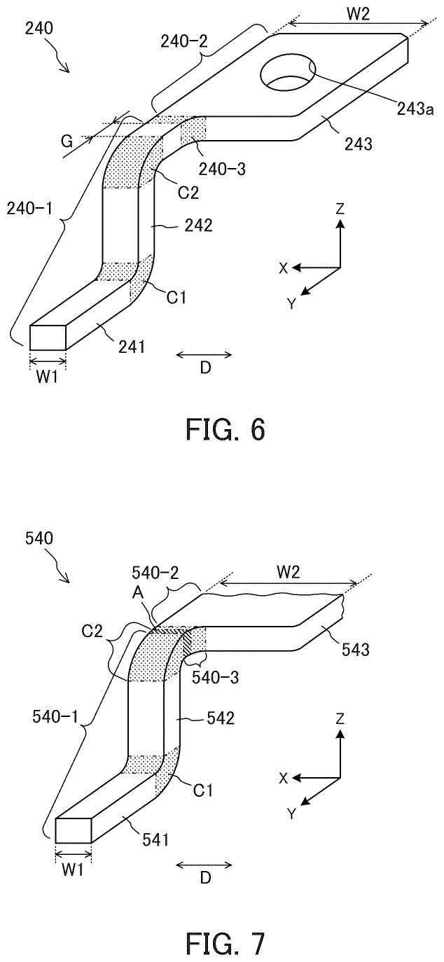

FIG. 6 is a perspective view illustrating the entirety of a P terminal 240 in the third embodiment.

In the P terminal 40 in the first embodiment and the P terminal 140 in the second embodiment described above, the second vertical portion 44 (the second vertical portion of the P terminal 140 is not illustrated) is provided between the extending portion 43, 143 and the external connection portion 45, 145. In the third embodiment, however, an external connection portion 243 is provided, instead of the extending portion 43, 143, as the extending portion extending parallel to the mounting surface from the first vertical portion 242 with the second bent portion C2 interposed between the external connection portion 243 and the first vertical portion 242.

Similarly to the P terminal 40 illustrated in FIG. 3, the P terminal 240 illustrated in FIG. 6 includes a narrow portion 240-1, a wide portion 240-2, and an expanding portion 240-3, and the second bent portion C2 and the expanding portion 240-3 are provided with a gap G therebetween. The external connection portion 243 is provided with a screw hole 243a connected to the external conductor 301 illustrated in FIG. 2.

Incidentally, the external connection portion 243 of the P terminal 240 may have a configuration similar to that of the extending portion 143 of the second embodiment illustrated in FIG. 4, that is, a configuration in which the cutout 143a is provided.

The external connection portion 243 is provided as a parallel portion as in the third embodiment, which allows the second vertical portion 44, disposed between the extending portion 43 and the external connection portion 45 as illustrated in FIG. 2, to be omitted. According to this configuration, the configuration of the P terminal 240 can be simplified, and the P terminal 240 can be easily manufactured.

Further, in the first to third embodiments described above, the first vertical portions 42, 142, and 242 are provided with the first bent portion C1 interposed between the first vertical portions 42, 142, and 242 and the portions to be bonded 41, 141, and 241; however, the first vertical portions 42, 142, and 242 may be provided with a portion extending parallel to the mounting surface or a plurality of bent portions interposed between the first vertical portions 42, 142, and 242 and the portions to be bonded 41, 141, and 241.

In the first to third embodiments, the first bent portion C1 and the second bent portion C2 bend the P terminal 40, 140, 240 in the Y direction or the Z direction, but a bent portion or the like that bends the P terminal 40, 140, 240 in the X direction may be provided.

In the first to third embodiments, the P terminals 40, 140, and 240 (portions to be bonded 41, 141, and 241) are ultrasonically bonded to the multilayer substrate 11. Instead, the portions to be bonded 41, 141, and 241 may be bonded to the multilayer substrate 11 using another bonding method such as solder bonding. Even in such a case, stress may be generated in the P terminals 40, 140, and 240 due to temperature change, vibrations, or the like at the time of bonding to the multilayer substrate 11 or at the time of using the semiconductor device 1 and, thus, the occurrence of cracks can be prevented as described above.

In the first to third embodiments, the configuration of the P terminals 40, 140, and 240 has been described as an example, but a configuration similar thereto may be adopted for the N terminals 50 and 150. In such a case, the N terminals 50 and 150 desirably have the same shape as the P terminals 40, 140, and 240 from the viewpoint of ease of manufacturing, but does not need to have the same shape. Although the M terminal 60 has a shape different from that of the P terminals 40, 140, and 240, a configuration similar to that of the P terminals 40, 140, and 240 described above may also be adopted for the M terminal 60.

Hereinafter, the invention described in the claims of the originally filed application will be additionally described.

### <Supplementary Note 1>

A semiconductor device including:
a multilayer substrate on which a semiconductor element is mounted; and
a main terminal bonded to the multilayer substrate, in which
the main terminal includes a narrow portion including a vertical portion extending in a direction perpendicular to a surface of the multilayer substrate on which the semiconductor element is mounted, and a wide portion having a width in a width direction perpendicular to a thickness direction and an extending direction of the main terminal larger than a width of the narrow portion,
the narrow portion is located on one end side of the wide portion in the width direction,
the main terminal is provided with an extending portion extending toward outside of the multilayer substrate with a bent portion interposed therebetween from an end of the vertical portion on a side opposite to the multilayer substrate,
the narrow portion extends at least over the vertical portion, the bent portion, and a part of the extending portion, and
the wide portion extends at least over another part of the extending portion different from the part of the extending portion.

### <Supplementary Note 2>

The semiconductor device according to supplementary note 1, in which
the main terminal further includes an expanding portion located between the narrow portion and the wide portion and having the width gradually increasing from the narrow portion toward the wide portion, and
the expanding portion is located closer to the extending portion than the bent portion with a gap interposed between the expanding portion and the bent portion.

### <Supplementary Note 3>

The semiconductor device according to supplementary note 1, in which
the extending portion is provided with a cutout adjacent to the narrow portion in the width direction, and
the cutout has a bottom portion located on a side opposite to the bent portion with respect to an end of the wide portion on the bent portion side.

### <Supplementary Note 4>

The semiconductor device according to supplementary note 1, further including
a case having a housing region in which the multilayer substrate is accommodated and a wall portion surrounding the housing region, in which
the narrow portion is located closer to the housing region than the wall portion, and
the wide portion extends from the housing region through the case.

### <Supplementary Note 5>

The semiconductor device according to supplementary note 1, in which
the main terminal is bonded to the multilayer substrate using ultrasonic bonding.

### <Supplementary Note 6>

The semiconductor device according to supplementary note 1, in which
the narrow portion extends over a portion to be bonded that extends parallel to the mounting surface and is bonded to the multilayer substrate.

### <Supplementary Note 7>

The semiconductor device according to supplementary note 1, in which
the wide portion extends over an external connection portion that extends parallel to the mounting surface and is connected to an external conductor.

### <Supplementary Note 8>

The semiconductor device according to supplementary note 7, in which
the wide portion extends over a second vertical portion that is provided between the extending portion and the external connection portion and extends in a direction perpendicular to the mounting surface.

### <Supplementary Note 9>

The semiconductor device according to supplementary note 7, in which
the external connection portion is the extending portion.

As described above, the present invention provides an effect of preventing the occurrence of a crack in a main terminal in a semiconductor device, and is useful for, for example, an inverter device for an in-vehicle or industrial motor.

What is claimed is:

1. A semiconductor device comprising:
a multilayer substrate on which a semiconductor element is mounted; and
a main terminal, including
a bonded portion bonded to a surface of the multilayer substrate, the bonded portion extending in an extending direction,
a vertical portion extending in a vertical direction perpendicular to the surface of the multilayer substrate, the vertical portion having a first end and a second end in the vertical direction, with the first end closer to the multilayer substrate,
an extending portion extending toward outside of the multilayer substrate, and
a bent portion interposed between the vertical portion and the extending portion, and extending from the second end of the vertical portion, to thereby form
a narrow portion that includes the bonded portion, the vertical portion, the bent portion, and a first part of the extending portion, and
a wide portion that includes a second part of the extending portion different from the first part, wherein
in a width direction perpendicular to the vertical direction and the extending direction, a width of the wide portion is larger than a width of the narrow portion, and
the narrow portion is located on one end side of the wide portion in the width direction.

2. The semiconductor device according to claim 1, wherein
the main terminal further includes an expanding portion formed between the narrow portion and the wide portion and having a width thereof gradually increasing from the narrow portion toward the wide portion, and
the expanding portion is located closer to the extending portion than the bent portion with a gap interposed between the expanding portion and the bent portion.

3. The semiconductor device according to claim 1, wherein
the extending portion is provided with a cutout adjacent to the narrow portion in the width direction, and
the cutout has a bottom portion that is recessed in the extending direction.

4. The semiconductor device according to claim 1, further comprising
a case, having:
a housing region in which the multilayer substrate is accommodated, and
a wall portion surrounding the housing region, wherein the narrow portion is located closer to the housing region than the wall portion, and the wide portion extends from the housing region through the case.

5. The semiconductor device according to claim 1, wherein
the main terminal is bonded to the multilayer substrate using ultrasonic bonding.

6. The semiconductor device according to claim 1, wherein
the bonded portion extends parallel to the mounting surface.

7. The semiconductor device according to claim 1, wherein
the wide portion further includes an external connection portion that extends parallel to the mounting surface and is configured to be connected to an external conductor.

8. The semiconductor device according to claim 7, wherein
the wide portion further includes a second vertical portion that is provided between the extending portion and the external connection portion, and extends in the vertical direction.

9. The semiconductor device according to claim 7, wherein
the external connection portion is the extending portion.
